(19) United States
(12) Patent Application Publication
(10) Pub. No.: US 2005/0263176 A1
(43) Pub. Date: Dec. 1, 2005

(54) Thermoelectric power generation system

(75) Inventors: Hiroo Yamaguchi, Toyohashi-city (JP); Yasutoshi Yamanaka, Kariya-city (JP)

Correspondence Address: HARNESS, DICKEY & PIERCE, P.L.C., P.O. BOX 828, BLOOMFIELD HILLS, MI, 48303, US

(73) Assignee: DENSO Corporation, Kariya-city (JP)

(21) Appl. No.: 11/136,314

(22) Filed: May 24, 2005

(30) Foreign Application Priority Data
May 26, 2004 (JP) 2004-156669

(51) Int. Cl. F25B 21/02; H01L 35/28

(52) U.S. Cl. 136/203

(57) ABSTRACT

A thermoelectric power generation system having a thermoelectric unit is provided for an engine, through which cooling water flows. A part of cooling water circulates through the engine and a radiator, where cooling water is cooled. Cooling water of a discharge side of the engine and that of a discharge side of the radiator are respectively used as a high-temperature side heat source and a low-temperature side heat source of the thermoelectric unit. Thus, the thermoelectric unit is provided with a steady temperature difference to generate power, without increasing a component number and deteriorating a cooling of the engine.

### CROSS REFERENCE TO RELATED APPLICATION

This application is based on Japanese Patent Application No. 2004-156669 filed on May 26, 2004, the disclosure of which is incorporated herein by reference.

### FIELD OF THE INVENTION

The present invention relates to a thermoelectric power generation system for recovering waste heat of an engine and converting heat energy into electric energy.

### BACKGROUND OF THE INVENTION

In general, a thermoelectric unit is used to recover waste heat of an internal-combustion engine and convert heat energy into electric energy.

For example, with reference to JP-10-238406A, the internal-combustion engine (engine) is communicated with a cooling water cycle circuit, in which a heat radiation device (radiator) is provided. High-temperature cooling water at the discharge side of the engine in the cooling water cycle circuit is used as a high-temperature side heat source of the thermoelectric unit. A heat radiation apparatus of a water-cooling type or an air-cooling type is used as a low-temperature side heat source of the thermoelectric unit. Thus, the thermoelectric unit generates electric power (power) by recovering waste heat of the engine. In this case, a heat sink is used as the heat radiation apparatus. The heat sink, being a natural air cooling type, is disposed at the front portion of a vehicle to use a traveling air.

Referring to JP-9-32636A, a heat recovery device (thermoelectric unit) is arranged between a first cooling water system and a second cooling water system, so as to be provided with a temperature difference to generate power. The first cooling water system is communicated with a cooling water jacket mounted at the body of the engine, so that cooling water is circulated by a first cooling water pump in the first cooling water system. The second cooling water system, in which cooling water is circulated independently from the first cooling water system, is provided with a radiator and a second cooling water pump, which adjusts the amount of cooling water circulated therein.

In the above-described thermoelectric units, it is necessary to respectively maintain a steady temperature difference. That is, the heat amount in the high-temperature side heat source is to approximately equal to that of the low-temperature side heat source, otherwise heat will be conducted from the high-temperature side heat source to the low-temperature side heat source by the thermoelectric unit so that the temperature difference therebetween tends to disappear.

However, in the case of JP-10-238406A, the heat radiation apparatus (low-temperature side heat source) is the natural water cooling type (using traveling air), to have an insufficient cooling capacity. Size-enlarging of the heat radiation apparatus or an addition of a cooling fan for improving the cooling capacity will be avoided, considering a mounting performance deterioration and a power (electric power) increase. Moreover, when the vehicle is stop, the traveling wind will disappear so that power cannot be generated.

In the case of JP-9-32636A, the first and second cooling water systems are separately provided with the pumps (first cooling water pump and second cooling water pump) for circulating cooling water. Moreover, electric circuits (electronic control units) are needed to control the pumps. Then, the component number and the power to be used are increased.

Moreover, in this case, the amount of cooling water circulated in the second cooling water system is controlled by the second cooling water pump to adjust temperature of cooling water in the first cooling water system through the thermoelectric unit, so that the body of the engine is cooled. Therefore, the thermoelectric unit is to have a high heat conductivity. As a result, the steady temperature difference cannot be maintained at the thermoelectric unit, so that the power-generation efficiency of the thermoelectric unit is deteriorated. On the other hand, if the heat conductivity of the thermoelectric unit is decreased, the cooling capacity of the radiator or power of the second cooling water pump needs to be increased.

### SUMMARY OF THE INVENTION

In view of the above-described disadvantages, it is an object of the present invention to provide a thermoelectric power generation system having a high power-generation efficiency for an engine. The thermoelectric power generation system has a thermoelectric unit, where a steady temperature difference is maintained without increasing a component number and deteriorating a cooling of the engine.

According to the present invention, a thermoelectric power generation system for an engine is provided with a radiator for cooling a part of cooling water flowing through the engine, and a thermoelectric unit having a high-temperature side heat source and a low-temperature side heat source. The high-temperature side heat source is cooling water of a discharge side of the engine. The low-temperature side heat source is cooling water of a discharge side of the radiator. The thermoelectric unit generates power due to a temperature difference between the high-temperature side heat source and the low-temperature side heat source.

Accordingly, the thermoelectric unit can be provided with a steady temperature difference by cooling water of the discharge side of the engine and that of the discharge side of the radiator, which respectively construct the high-temperature side and low-temperature side heat sources of the thermoelectric unit. Thus, the thermoelectric power generation system has a high energy-generation efficiency, as compared with the case referring to JP-10-238406A where a heat radiation apparatus of a natural air cooling type is used as a low-temperature side heat source.

Moreover, because cooing water having been cooled by the radiator is used as the low-temperature side heat source with respect to cooling water of the discharge side of the engine, a decrease of the power-generation efficiency for cooling the engine (referring to JP-9-32636A) can be prevented.

Preferably, the thermoelectric power generation system has an engine cooling-water circuit, through which cooling water is circulated to flow through the engine and the radiator. The engine cooling-water circuit has a parallel passage which is connected with the radiator in parallel. The high-temperature side heat source of the thermoelectric unit is cooling water of the discharge side of the engine, which flows through the parallel passage.

Because the thermoelectric power generation system (high-temperature side heat source unit) is connected with the radiator in parallel, the engine cooling-water circuit has a smaller flowing-water resistance than the case where the thermoelectric power generation system is connected with the radiator in series. Accordingly, the amount of cooling water flowing through the engine can be maintained. Thus, a power increase of a water pump for circulating cooling water through the engine can be prevented.

More preferably, the engine cooling-water circuit has a bypass passage for bypassing the radiator, and a radiator-downstream passage between a downstream side of the radiator and an upstream side of the bypass passage. The low-temperature side heat source of the thermoelectric unit is cooling water of the discharge side of the radiator, which flows through the radiator-downstream passage.

Therefore, in the case where the temperature of cooling water is low during a low-temperature startup of the engine, cooling water will flow through the bypass passage, thus promoting warming-up of the engine. When the temperature of cooling water is sufficiently increased, cooling water will flow through the radiator to be cooled. Then, the thermoelectric unit is provided with a satisfactory temperature difference, thus efficiently generating power.

More preferably, the radiator includes a heat radiation unit, which has a first heat radiation portion with a predetermined heat radiation capacity and a second heat radiation portion. Cooling water flowing through the second heat radiation portion is less than that flowing through the first heat radiation portion. The radiator-downstream passage includes a first passage and a second passage, which are connected with each other in parallel. Cooling water passing the first heat radiation portion flows into the first passage. Cooling water passing the second heat radiation portion flows into the second passage. The low-temperature side heat source of the thermoelectric unit is cooling water of the discharge side of the radiator, which flows through the second passage.

Accordingly, the temperature of cooling water from the discharge side of the second heat radiation portion can be set lower than that from the discharge side of the first heat radiation portion. Thus, the temperature difference between the high-temperature side heat source and low-temperature side heat source unit can be increased, so that the amount of power generated by the thermoelectric unit can be increased.

### BRIEF DESCRIPTION OF THE DRAWINGS

Other objects, features and advantages of the present invention will become more apparent from the following detailed description made with reference to the accompanying drawings, in which:

FIG. 1 is a schematic diagram showing a thermoelectric power generation system 100 according to a first embodiment of the present invention;

FIG. 2 is a schematic diagram showing a thermoelectric power generation system 100 according to a first modification of the first embodiment;

FIG. 3 is a schematic diagram showing a thermoelectric power generation system 100 according to a second modification of the first embodiment;

FIG. 4 is a schematic diagram showing a thermoelectric power generation system 100 according to a second embodiment of the present invention;

FIG. 5 is a schematic diagram showing a thermoelectric power generation system 100 according to a third embodiment of the present invention;

FIG. 6 is a schematic diagram showing a thermoelectric power generation system 100 according to a first modification of the third embodiment; and

FIG. 7 is a schematic diagram showing a thermoelectric power generation system 100 according to a second modification of the third embodiment.

### DETAILED DESCRIPTION OF THE PREFERRED EMBODIMENT

### First Embodiment

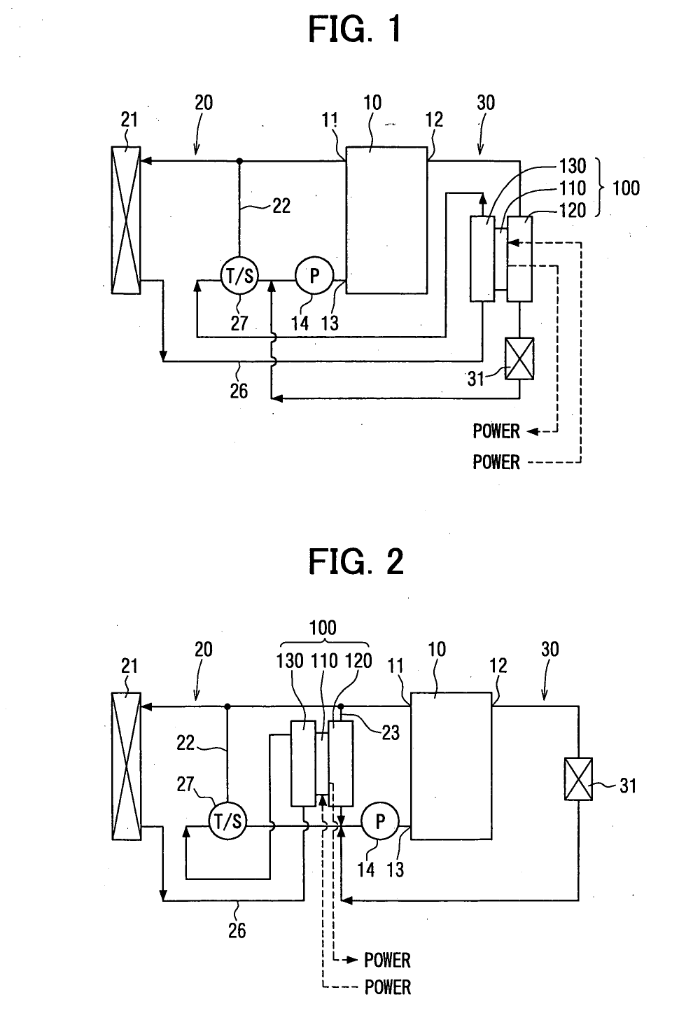

A thermoelectric power generation system 100 according to a first embodiment of the present invention will be described with reference to FIGS. 1-3. The thermoelectric power generation system 100 is suitably used in a vehicle having an engine 10 of a water-cooling type, to recover waste heat of the engine 10 and convert heat energy into electric energy.

The thermoelectric power generation system 100 has a high-temperature side heat source unit 120, a low-temperature side heat source unit 130, and a thermoelectric unit 110 having two side surfaces which respectively tightly contact the high-temperature side and low-temperature side heat source units 120, 130. Cooling water of the engine 10 is circulated to flow through the high-temperature side heat source unit 120 and the low-temperature side heat source unit 130, to be used as a high-temperature side heat source and low-temperature side heat source of the thermoelectric unit 110.

Each of the high-temperature side and low-temperature side heat source units 120, 130, being made of, for example, a metal, is a thin rectangle container, in which multiple inner fins are inserted. The high-temperature side heat source unit 120 tightly contacts the one side surface of the thermoelectric unit 110, while an electrically isolating material and a heat-conductive material (e.g., heat-conductive sheet or grease) for reducing a thermal contact resistance is arranged between the high-temperature side heat source unit 120 and the side surface.

The low-temperature side heat source unit 130 tightly contacts the other side surface of the thermoelectric unit 110, while an electrically isolating material and a heat-conductive material (e.g., heat-conductive sheet or grease) for reducing a thermal contact resistance is arranged between the low-temperature side heat source unit 130 and the other side surface. The high-temperature side and low-temperature side heat source units 120, 130 are respectively arranged in a heater hot-water circuit 30 and an engine cooling-water circuit 20, so that cooling water flowing therein is separately used as the high-temperature side heat source and the low-temperature side heat source of the thermoelectric unit 110.

The thermoelectric unit 110 is constructed of a P-type semiconductor and a N-type semiconductor which are connected with each other in series through a metal electrode, to generate electric power (generate power) by a seebeck effect or produce heat by a peltier effect.

As shown in FIG. 1, the engine cooling-water circuit 20, in which the low-temperature side heat source unit 130 is arranged, is communicated with the engine 10 through a first outlet 11 and an inlet 13 of the engine 10. A water pump 14 and a radiator 2 are provided in the engine cooling-water circuit 20, so that cooling water from the first outlet 11 of the engine 10 is circulated by the water pump 14 to pass the radiator 21, where cooling water radiates heat to be cooled, and flow into the inlet 13 of the engine 10. Thus, the operation temperature of the engine 10 is maintained to be appropriate. In this case, the water pump 14 is an engine-driving-type pump driven by the engine 10.

The engine cooling-water circuit 20 is further provided with a bypass passage 22, being connected with the radiator 21 in parallel, and a thermostat 27 for adjusting amounts of cooling water flowing through the radiator 21 and that through the bypass passage 22. Thus, cooling water can be adjusted to flow through the bypass passage 22 to bypass the radiator 21.

Specifically, when the temperature of cooling water is lower than or equal to a first predetermined value (e.g., 85° C.), the open degree of the thermostat 27 at the side of the radiator 21 is controlled to be minimum so that cooling water flows through the bypass passage 22 to bypass the radiator 21. Thus, cooling water is prevented from being overcooled, in the case where cooling water has a relatively low temperature, for example, immediately after the engine 10 is activated. Thus, warming-up of the engine 10 is promoted.

On the other hand, when the temperature of cooling water is higher than the first predetermined value, the open degree of the thermostat 27 is adjusted so that cooling water flows through both the radiator 21 and the bypass passage 22. When the temperature of cooling water is higher than or equal to a second predetermined value (for example, 90° C.), the open degree of the thermostat 27 at the side of the radiator 21 will become maximum to wholly open the passage of the side of the radiator 21, and completely close the bypass passage 22.

In the engine cooling-water circuit 20, the passage between the downstream side of the radiator 21 and the upstream side of the bypass passage 22 (thermostat 27) is named a radiator-downstream passage 26, in which the low-temperature side heat source unit 130 is arranged.

The engine 10 is further communicated with the heater hot-water circuit 30, which is connected to the second outlet 12 of the engine 10 and the upstream side of the water pump 14 of the engine cooling-water circuit 20. The high-temperature side heat source unit 120 and a heater core 31 are arranged in the heater hot-water circuit 30 between the second outlet 12 and the upstream side of the water pump 14. Then, a part of cooling water of the engine 10 can be circulated by the water pump 14 to flow through the high-temperature side heat source unit 120 and the heater core 31, which is a heating heat exchanger for conditioning air by using cooling water (hot water) of the engine 10 as a heat source.

In this case, cooling water (cooling water of discharge side of engine) flowing from the second outlet 12 of the engine 10 and circulated in the heater hot-water circuit 30 has a higher temperature than cooling water flowing through the radiator-downstream passage 26 where the high-temperature side heat source unit 120 is arranged, because the radiator-downstream passage 26 is arranged at the downstream side of the radiator 21.

That is, in the engine cooling-water circuit 20, cooling water (cooling water of discharge side of radiator) having past the radiator 21 flows through the low-temperature side heat source unit 130 (radiator-downstream passage 26) to be used as the low-temperature heat source of the thermoelectric unit 110. In the heater hot-water circuit 30, cooling water (cooling water of discharge side of engine) flows through the high-temperature side heat source unit 120 to be used as the high-temperature heat source of the thermoelectric unit 110. Thus, the thermoelectric unit 110 is provided with a temperature difference between the two side surfaces thereof, to generate power.

Next, the operation and effect of the thermoelectric power generation system 100 will be described.

When the engine 10 is activated, the water pump 14 will be driven to circulate cooling water in the engine cooling-water circuit 20 and the heater hot-water circuit 30. In the engine cooling-water circuit 20, when the temperature of cooling water discharged from the first outlet 11 of the engine 10 is lower than or equal to the first predetermined value, cooling water is adjusted by the thermostat 27 to flow through the bypass passage 22. The engine 10 produces heat while operating, so that the temperature of cooling water increases. When the temperature of cooling water is higher than the first predetermined value, at least a part of cooling water from the first outlet 11 of the engine 10 is adjusted to pass the radiator 21, thereafter flowing into the radiator-downstream circuit 26.

Therefore, cooling water circulated in the heater hot-water circuit 30 flows through the high-temperature side heat source unit 120, while cooling water flowing through the radiator-downstream circuit 26 passes the low-temperature side heat source unit 130. Here, cooling water through the low-temperature side heat source unit 130 has been cooled by the radiator 21 to have a lower temperature than that of cooling water through the high-temperature side heat source unit 120, so that a temperature difference is caused between the two heat source units 120 and 130 which respectively contact the side surfaces of the thermoelectric unit 110. Thus, the thermoelectric unit 110 generates power due to the seebeck effect.

The generated power by the thermoelectric unit 110 can be supplied for peripheral devices (auxiliary devices) of the engine 10 or charge a battery (not shown), for example.

In the case where the temperature of cooling water is relatively low (that is, it takes relatively long time for the temperature to increase), for example, when the engine 10 is activated at a low temperature, the thermoelectric unit 110 will be energized by the battery or the like to produce heat due to the peltier effect (heat-production function) so that cooling water passing the high-temperature side heat source unit 120 in the heater hot-water circuit 30 is heated.

According to the present invention, in the heater hot-water circuit 30, cooling water discharged from the engine 10 flows through the high-temperature side heat source unit 120 to be used as the high-temperature side heat source of the thermoelectric unit 110. In the engine cooling-water circuit 20, cooling water discharged from the radiator 21 flows through the low-temperature side heat source unit 130 to be used as the low-temperature side heat source of the thermoelectric unit 110.

Therefore, as compared with the device described in JP-10-238406A, the thermoelectric power generation system 100 according to the present invention can provide a steady temperature difference for the thermoelectric unit 110, thus having a satisfactory power-generation efficiency.

Moreover, in this case, cooling water of the engine 10 is used as the high-temperature side and low-temperature side heat sources. That is, cooling water directly from the engine 10 is used as the high-temperature side heat source, while cooling water which flows from the engine 10 and is cooled by the radiator 21 is used as the low-temperature side heat source with respect to the high-temperature side heat source. Therefore, a power-generation efficiency reduction due to a cooling of the engine 10, which occurs in the device described in JP-9-32636A, can be avoided.

Furthermore, according to this embodiment, cooling water of the engine 10 is circulated in the heater hot-water circuit 30 and the engine cooling-water circuit 20 by the single water pump 14, without using multiple pumps and electric circuits for controlling the pumps, as described in JP-9-32636A. Thus, the component number can be reduced.

Based on the first embodiment, the thermoelectric unit 110 can be supplied power to heat (that is, convert electric energy into heat energy) cooling water flowing in the heater hot-water circuit 30, in the case where the engine 10 is activated at low temperature. Thus, warming-up of the engine 10 is promoted. Accordingly, the friction loss of the engine 10 is decreased, so that a fuel cost thereof is reduced. Furthermore, the heating capacity of the heater core 31 is improved.

Moreover, in the case where the temperature of cooling water is low during the low-temperature startup of the engine 10 or the like, cooling water will flow through the bypass passage 22, thus promoting warming-up of the engine 10. When the temperature of cooling water is sufficiently increased, cooling water will be adjusted to flow through the radiator 21 to be cooled, thereafter passing the low-temperature side heat source unit 130. Therefore, a satisfactory temperature difference can be maintained between the high-temperature side and low-temperature side heat source units 120, 130, so that the thermoelectric unit 110 can efficiently generate power.

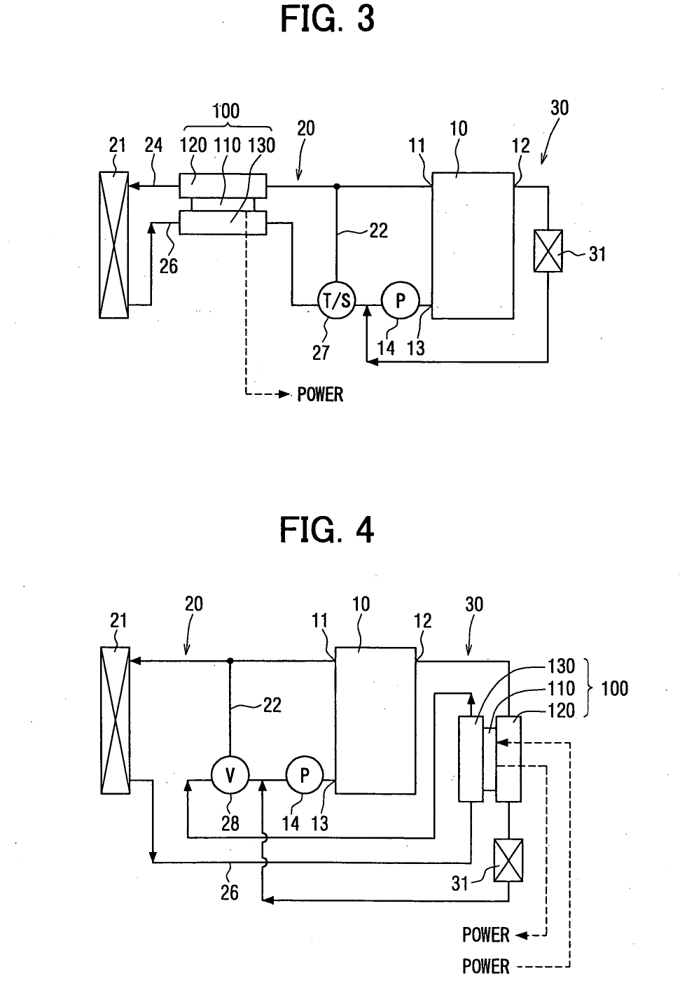

A first modification and a second modification of the first embodiment are respectively shown in FIGS. 2 and 3. In the modifications, cooling water used as the high-temperature side heat source of the thermoelectric unit 110 is changed. That is, the arrangement of the high-temperature side heat source unit 120 is changed.

According to the first modification with reference to FIG. 2, a parallel passage 23 is additionally provided in the engine cooling-water circuit 20, and arranged between the discharge side (that is, upstream side of bypass passage 22) of the engine 10 and the upstream side of the water pump 14. That is, the parallel passage 23 is connected with the radiator 21 in parallel. The high-temperature side heat source unit 120 is arranged in the parallel passage 23, so that cooling water (cooling water of discharging side of engine 10) will pass the high-temperature side heat source unit 120 to be used as the high-temperature side heat source.

Accordingly, similar to the first embodiment, the component number of the thermoelectric power generation system 100 based on the first modification can be reduced. Moreover, a steady temperature difference can be maintained between the high-temperature side and low-temperature side heat source units 120, 130 of the thermoelectric unit 110, so that the thermoelectric power generation system 100 has a satisfactory power-generation efficiency. Furthermore, cooling water flowing through the parallel passage 23 can be heated by the thermoelectric unit 110 due to the peltier effect thereof, thus promoting the warming-up of the engine 10.

In the engine cooling-water circuit 20 based on the first modification, the high-temperature side heat source unit 120 is arranged in the parallel passage 23 which is connected with the radiator 21 in parallel, so that the engine cooling-water circuit 20 has a smaller resistance (flowing-water resistance) against a flowing of cooing water, as compared with the case where the high-temperature side heat source unit 120 is connected with the radiator 21 in series. Therefore, according to the first modification, cooling water passing the engine 10 can be maintained. Thus, a power increase (for circulating cooling water to flow through the engine 10) of the water pump 14 can be prevented.

In this case, the low-temperature side heat source unit 130 is arranged in the radiator-downstream passage 26 of the engine cooling-water circuit 20, which is the same with the first embodiment. Therefore, cooling water having been cooled in the radiator 21 flows through the low-temperature side heat source unit 130. Thus, the thermoelectric unit 110 is provided with a temperature difference to generate power.

According to the second modification shown in FIG. 3, in the engine cooling-water circuit 20, the high-temperature side heat source unit 120 is arranged in the passage (named a radiator-upstream passage 24), which is between the side of the bypass passage 22 and the upstream side of the radiator 21. Thus, cooling water of the discharging side of the engine 10 flows through the high-temperature side heat source unit 120 to be used as the high-temperature side heat source. The low-temperature side heat source unit 130 is arranged in the radiator-downstream passage 26 of the engine cooling-water circuit 20, which is the same with the first embodiment. In this case, the heat-production function of the thermoelectric unit 110 due to the peltier effect is omitted. Then, warming-up of the engine 10 by the thermoelectric unit 110 is omitted.

According to the second modification, the component number of the thermoelectric power generation system 100 can be reduced. Furthermore, the thermoelectric unit 110 can be provided with a steady temperature difference, thus having a satisfactory power-generation efficiency

### Second Embodiment

A second embodiment of the present invention will be described referring to FIG. 4. In this case, a flow-amount adjusting valve 28, the opening degree of which is controlled by a control unit (not shown), is used instead of the thermostat 27 in the above-described first embodiment.

The flow-amount adjusting valve 28, being arranged in the engine cooling-water circuit 20, is a three-way electromagnetic valve connected with the sides of the radiator 21, the bypass passage 22 and the engine 10. The opening degree of the flow-amount adjusting valve 28 at the side of the bypass passage 22 can be adjusted by the control unit from 100% to 0%, while the opening degree thereof at the side of the radiator 21 can be adjusted from 0% to 100% responding to the opening degree thereof at the side of the bypass passage 22. In this case, the sides of the radiator 21 and the bypass passage 22 are separately connected with the side of the engine 10 through the flow-amount adjusting valve 28.

In the first embodiment where the thermostat 27 is used, the amounts of cooling water flowing through the radiator 21 and the bypass passage 22 are controlled according to the temperature of cooling water, and the thermoelectric unit 110 generates power only in the case where cooling water flows through the radiator 21. According to the second embodiment, cooling water can be adjusted by the flow-amount adjusting valve 28 to flow through the radiator 21 and the bypass passage 22 regardless of the temperature of cooling water. Therefore, it is possible to delicately control the power generation, warming up of the engine 10, cooling of the engine 10 and the like.

### Third Embodiment

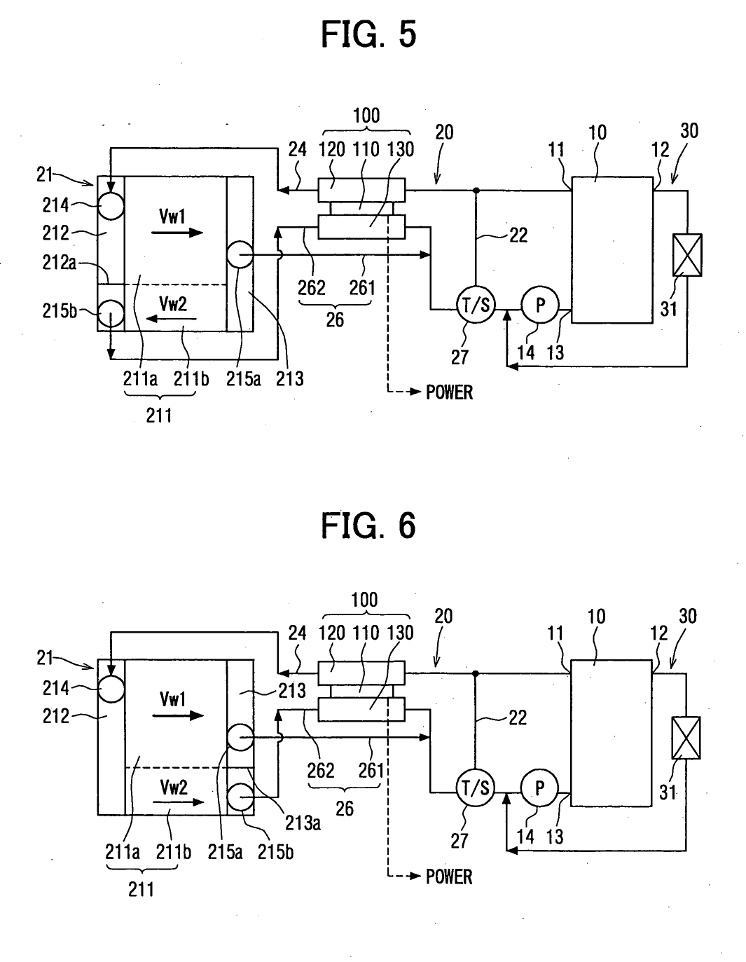

A third embodiment of the present invention will be described referring to FIGS. 5-7. In this embodiment, the arrangements of the high-temperature side and low-temperature side heat source units 120, 130 in the engine cooling-water circuit 20 are the same with the second modification (referring to FIG. 3) of the first embodiment, while the temperature of cooling water discharged from the radiator 21 to the low-temperature side heat source unit 130 is further decreased.

The radiator 21 has an inlet side tank 212, an outlet side tank 213, and a heat radiation unit 211 arranged between the inlet and outlet side tanks 212, 213. According to the third embodiment, the heat radiation unit 211 is divided into a first heat radiation portion 211a and a second heat radiation portion 211b. The first heat radiation portion 211a has a size to maintain a predetermined heat radiation capacity. For example, the first heat radiation portion 211a has a size being 70% of that of the heat radiation unit 211, and the second heat radiation portion 211b has a size being 30% of that of the heat radiation unit 211.

A partition member 212a (e.g., partition plate) is arranged in the inlet side tank 212 at the position corresponding to the border between the first and second heat radiation portions 211a, 211b.

The inlet side tank 212 is provided with an inlet 214 at the side of the first heat radiation portion 211a, and a second outlet 215b at the side of the second heat radiation portion 211b. The outlet side tank 213 is provided with a first outlet 215a, which is disposed at the side of the first heat radiation portion 211a and near the side of the second heat radiation portion 211b.

In this case, the radiator-downstream circuit 26 is divided into a first passage 261 and a second passage 262, which are connected with each other in parallel. That is, the downstream sides of the first and second passages 261, 262 are connected to the upstream side of the thermostat 27, and the upstream sides of the first and second passages 261, 262 are respectively connected with the first outlet 215a and the second outlet 215b of the radiator 21. In this case, the low-temperature side heat source unit 130 is arranged in the second passage 262.

Cooling water is introduced into the radiator 21 from the inlet 214 thereof and flows through the first heat radiation portion 211a. Thereafter, more (flow amount Vw1) of cooling water is discharged from the radiator 21 through the first outlet 215a to flow into the first passage 261. The remain (flow amount Vw2) of cooling water makes a U-turn in the first heat radiation portion 211a to flow into the second heat radiation portion 211b, thereafter discharged from the radiator 21 through the second outlet 215b to flow into the second passage 262. That is, cooling water having passed the second heat radiation portion 211b is used as the low-temperature side heat source of the thermoelectric unit 110. On the other hand, the high-temperature side heat source unit 120 is arranged in the radiator-upstream passage 24, so that the thermoelectric unit 110 is provided with a temperature difference to generate power.

In this case, the flow amount Vw2 of cooling water passing the second heat radiation portion 211b is set smaller than the flow amount Vw1 of cooling water only flowing through the first heat radiation portion 211a, by adjusting the position of the first outlet 215a, the difference between the flowing-water resistances of the heat radiation portions 211a and 211b, and the difference between the flowing-water resistances of the first and second passages 261, 262. In this case, the second heat radiation portion 211b has a larger resistance than the first heat radiation portion 211a, and the second passage 262 has a larger resistance than the first passage 261.

Therefore, according to the third embodiment, the temperature of cooling water from the discharge side (second outlet 215b) of the second heat radiation portion 211b can be set lower than that from the discharge side (first outlet 215a) of the first heat radiation portion 211a. Accordingly, the temperature difference between the high-temperature side heat source unit 120 and low-temperature side heat source unit 130 can be increased, so that the amount of power generated by the thermoelectric unit 110 can be increased.

In the third embodiment, the inlet side tank 212 of the radiator 21 is provided with the partition member 212a at the position corresponding to the border between the first and second heat radiation portions 211a, 211b. According to a first modification of the third embodiment, the outlet side tank 213 of the radiator 21 is provided with a partition member 213a, which is disposed at the border between the sides of the first and second heat radiation portions 211a and 211b, referring to FIG. 6. In this case, the inlet side tank 212 is not provided with the partition member 212a.

In the first modification, the outlet side tank 213 is provided with the first outlet 215a and the second outlet 215b, which are respectively arranged at the sides of the first and second heat radiation portions 211a and 211b.

In this case, the flowing-water resistance of the second passage 262 is set smaller than that of the first passage 261. Therefore, more (flow amount Vw1) of cooling water passes the first heat radiation portion 211a, thereafter discharged from the radiator 21 through the first outlet 215a to flow into the first passage 261. The remain (flow amount Vw2) of cooling water passes the second heat radiation portion 211b, thereafter discharged from the radiator 21 through the second outlet 215b to flow into the second passage 262. Thus, temperature of cooling water discharged from the second outlet 215b (second heat radiation portion 211b) is lower than that from the first outlet 215a (first heat radiation portion 211a).

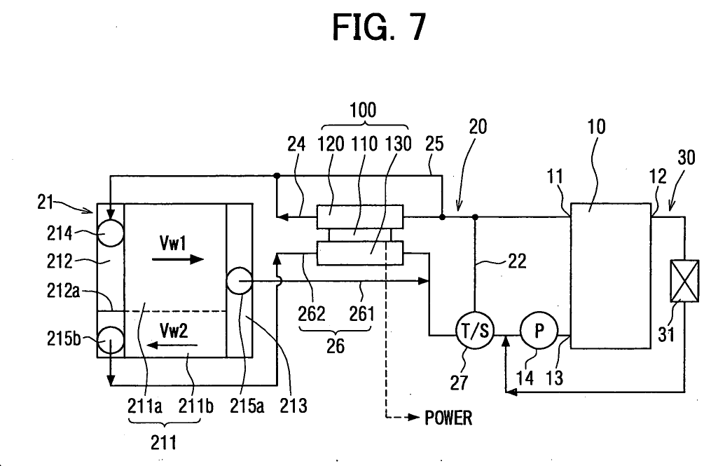

Furthermore, FIG. 7 shows a second modification of the third embodiment (referring to FIG. 5). In the second modification, a flowing-water resistance adjusting passage 25 is additionally provided in the engine cooling-water circuit 20, and connected with the high-temperature side heat source unit 120 in parallel. That is, the flowing-water resistance adjusting passage 25 is connected in parallel with the radiator-upstream passage 24, in which the high-temperature side heat source unit 120 is arranged.

Thus, the flowing-water resistance of the engine cooling-water circuit 20, which has an increased resistance due to a connection of the high-temperature side heat source unit 120 with the radiator 21 in series, can be adjusted by the flowing-water resistance adjusting passage 25 to reduce. Thus, cooling water flowing through the engine 10 can be restricted from decreasing.

1. A thermoelectric power generation system for an engine of a vehicle, the thermoelectric power generation system comprising:
a radiator for cooling a part of cooling water flowing through the engine; and
a thermoelectric unit having a high-temperature side heat source and a low-temperature side heat source, wherein:
the high-temperature side heat source is cooling water of a discharge side of the engine;
the low-temperature side heat source is cooling water of a discharge side of the radiator; and
the thermoelectric unit generates power due to a temperature difference between the high-temperature side heat source and the low-temperature side heat source.

2. The thermoelectric power generation system according to claim 1, further comprising
a heater hot-water circuit, through which cooling water is circulated to flow through the engine and a heater core of the vehicle, wherein
the high-temperature side heat source of the thermoelectric unit is cooling water of the discharge side of the engine, which flows through the heater hot-water circuit.

3. The thermoelectric power generation system according to claim 1, further comprising
an engine cooling-water circuit, through which cooling water is circulated to flow through the engine and the radiator, the engine cooling-water circuit having a parallel passage which is connected with the radiator in parallel, wherein
the high-temperature side heat source of the thermoelectric unit is cooling water of the discharge side of the engine, which flows through the parallel passage.

4. The thermoelectric power generation system according to claim 2, wherein
when the thermoelectric unit is supplied with electric power, the thermoelectric unit produces heat to heat cooling water flowing through the heater hot-water circuit.

5. The thermoelectric power generation system according to claim 1, further comprising
an engine cooling-water circuit, through which cooling water is circulated to flow through the engine and the radiator,
the engine cooling-water circuit having a bypass passage for bypassing the radiator, a radiator-upstream passage between a side of the bypass passage and an upstream side of the radiator, and a flowing-water resistance adjusting passage for adjusting a flowing-water resistance of the engine cooling-water circuit, wherein
the high-temperature side heat source of the thermoelectric unit is cooling water of the discharge side of the engine, which flows through the radiator-upstream passage.

6. The thermoelectric power generation system according to claim 1, further comprising
an engine cooling-water circuit, through which cooling water is circulated to flow through the engine and the radiator,
the engine cooling-water circuit having a bypass passage for bypassing the radiator, and a radiator-downstream passage between a downstream side of the radiator and an upstream side of the bypass passage, wherein
the low-temperature side heat source of the thermoelectric unit is cooling water of the discharge side of the radiator, which flows through the radiator-downstream passage.

7. The thermoelectric power generation system according to claim 6, wherein:
the radiator includes a heat radiation unit, which has a first heat radiation portion with a predetermined heat radiation capacity and a second heat radiation portion, cooling water flowing through the second heat radiation portion being less than that flowing through the first heat radiation portion;
the radiator-downstream passage includes a first passage and a second passage, which are connected with each other in parallel;
cooling water passing the first heat radiation portion flows into the first passage;
cooling water passing the second heat radiation portion flows into the second passage; and
the low-temperature side heat source of the thermoelectric unit is cooling water of the discharge side of the radiator, which flows through the second passage.

8. The thermoelectric power generation system according to claim 6, further comprising
a flow-amount adjusting valve, an opening degree of which is capable of being changed to adjust amounts of cooling water passing the radiator and that passing the bypass passage.

9. The thermoelectric power generation system according to claim 1, further comprising
a water pump for circulating both cooling water of the low-temperature side heat source and cooling water of the high-temperature side heat source of the thermoelectric unit.

10. The thermoelectric power generation system according to claim 5, wherein
the flowing-water resistance adjusting passage is connected with the radiator-upstream passage in parallel.

11. The thermoelectric power generation system according to claim 8, wherein
the flow-amount adjusting valve is a three-way electromagnetic valve, which is arranged in the engine cooling-water circuit and connected with sides of the radiator, the bypass passage and the engine.

12. The thermoelectric power generation system according to claim 3, wherein
when the thermoelectric unit is supplied with electric power, the thermoelectric unit produces heat to heat cooling water flowing through the parallel passage.
